(19) United States
(12) Patent Application Publication
(10) Pub. No.: US 2021/0285841 A1
(43) Pub. Date: Sep. 16, 2021

(54) USING INGRESS FOR LEAKAGE DETERMINATION IN CABLE NETWORKS

(71) Applicant: EFFIGIS GÉO-SOLUTIONS INC., Montreal (CA)

(72) Inventor: Magella BOUCHARD, Montreal (CA)

(21) Appl. No.: 17/200,371

(22) Filed: Mar. 12, 2021

Related U.S. Application Data
(60) Provisional application No. 62/989,615, filed on Mar. 14, 2020.

(51) Int. Cl. G01M 3/18; G01R 31/08

(52) U.S. Cl. CPC G01M 3/181; H01B 9/005; G01R 31/083

(57) ABSTRACT

There is described a method for locating and determining an intensity of a signal egress leakage of a fault, within a hybrid fiber-coaxial cable distribution network with an upstream frequency band encompassing an aeronautical band spanning over a range between 120 MHz and 140 MHz. The cable distribution network comprises a head station for transmitting content to subscribers at downstream frequencies within a network bandwidth. A radio-frequency signal having a carrier frequency within the aeronautical band is transmitted from a vehicle, emitted at a transmitter power in a decibel scale, thereby defining E_{P}, and then received at the head station of the cable distribution network. A measurement is made to determine a sum of a return signal level at leakage point (V_{L}) and a voltage induced at leakage point L (V_{P}), and the intensity of a signal egress leakage E_{L} of the fault is determined.

### CROSS-REFERENCE TO RELATED APPLICATIONS

This application claims priority from U.S. provisional patent application No. 62/989,615 filed on Mar. 14, 2020, the specification of which is hereby incorporated by reference.

### BACKGROUND

### (a) Field

The subject matter disclosed generally relates to a system and a method for assessing a Cumulative Leakage Index (CLI), and more generally, electromagnetic leakage from a high-split hybrid fiber coaxial network, without having to measure any leaked signals.

### (b) Related Prior Art

Among the more difficult problems faced by the broadband cable industry are those caused by signal leakage (egress) and ingress interferences. These interferences are caused by improper or defective RF shielding of passive or active components connected to the coaxial network. When signal leakage is present, it could cause potential impairments to licensed over-the-air services. When ingress interference is present, it could cause potential impairments to cable television data services. Ingress interfering signals can be generated by electromagnetic interference (EMI), radio-frequency interference (RFI) or TV interference (WI).

Cumulative Leakage Index (CLI) denotes an estimate of the cumulative impacts of leakage on aeronautical spectrum users. Various methods were developed and used in the past years to detect leakage (egress) and ingress faults in a low-split network.

Low-split systems have been in use traditionally in past years. In North America, low-split refers to 5 MHz to 42 MHz with downstream spectrum beginning at 54 MHz. European standards use different frequencies.

Networks are currently being updated to high-split hybrid fiber coaxial networks. High-split refers to the 5-200 MHz frequency range, with the 5-42 MHz range acting as a legacy spectrum range.

The methods that were used for low-split networks are not applicable for high-split networks due to the considerable expansion of the frequency spectrum, including high frequencies in which emission may be prohibited or hard to achieve.

### SUMMARY

According to an aspect, there is provided a method for locating and determining an intensity of a signal egress leakage of a fault, within a hybrid fiber-coaxial cable distribution network with an upstream frequency band encompassing an aeronautical band spanning over a range between 120 MHz and 140 MHz, the cable distribution network comprising a head station for transmitting content to subscribers at downstream frequencies within a network bandwidth, the method comprising:
transmitting from a vehicle, a radio-frequency signal having a carrier frequency within the aeronautical band, emitted at a transmitter power in a decibel scale, thereby defining E_{P};
receiving the radio-frequency signal at the head station of the cable distribution network,
measuring, at the head station, a sum (V_{P}+V_{L}) of a return signal level at leakage point (V_{L}) and a voltage induced at leakage point L (V_{P}) both converted into a decibel scale; and
determining the intensity of a signal egress leakage E_{L} of the fault by calculating E_{L}=V_{P}+V_{L}−E_{P}+116.5 in decibel scale.

According to another aspect, there is provided a method for locating and determining an intensity of a signal egress leakage of a fault, without detecting or measuring the signal egress leakage, within a hybrid coaxial-fiber cable distribution network with an upstream frequency band encompassing an aeronautical band spanning over a range between 120 MHz and 140 MHz, the cable distribution network comprising a head station for transmitting content to subscribers at downstream frequencies within a network bandwidth, the method comprising:
transmitting from a vehicle, geo-location information indicating a geographical position of the vehicle in a radio signal having a carrier frequency within the aeronautical band, emitted at a transmitter power in a decibel scale E_{P};
receiving the radio signal at the head station of the cable distribution network,
measuring, at the head station, a sum (V_{L}+V_{P}) of a return signal level at leakage point in dBmV (V_{L}) and a voltage induced at leakage point L in dBmV (V_{P}) both converted into a decibel scale;
extracting geo-location information from said radio signal to determine the location of the signal ingress point within the cable distribution network; and
determining the intensity of a signal egress leakage E_{L} of the fault by calculating E_{L}=V_{P}+V_{L}−E_{P}+116.5 in decibel scale.

### BRIEF DESCRIPTION OF THE DRAWINGS

Further features and advantages of the present disclosure will become apparent from the following detailed description, taken in combination with the appended drawings, in which:

FIG. 1 is a schematic diagram which illustrates an example of a system for detecting signal ingress interferences which are used to estimate equivalent leakage egress interferences, in accordance with an embodiment;

FIG. 2 is a graphical illustration of possible carrier frequencies in the return path spectrum that may be used for sending ingress signals, according to the prior art, with respect to the goal of determining ingress as such;

FIG. 3 is a block diagram of a method of determining equivalent egress leakage using detected signal ingress interferences, in accordance with an embodiment;

FIG. 4 is a graphical illustration of possible carrier frequencies in the return path spectrum that may be used for sending ingress signals, according to an embodiment, with the goal of determining equivalent egress leakage;

FIG. 5 is a schematic diagram which illustrates a high split network with a fault causing egress leakage, in accordance with an embodiment; and

FIG. 6 is a schematic diagram which illustrates a high split network with a fault causing egress leakage, and being characterized by measuring ingress signals instead, in accordance with an embodiment.

It will be noted that throughout the appended drawings, like features are identified by like reference numerals.

### DETAILED DESCRIPTION

HFC cable operators are considering the possibility of increasing the bandwidth used for High Split Network signals. In North America the vast majority of networks use a return band from 5 to 50 MHz. To increase the capacity of the return channel, the return band is considered to be extended up to, and even over, 204 MHz. The use of this new configuration would have a direct impact on the detection of cable leakage and, by the same token, the calculation of the CLI (Cumulative Leakage Index). For the purpose of measuring CLI, the measurements of the cable networks' radiation must be made near or within the aeronautical band (120 to 140 MHz). Since the latter is included inside the return band (also known as the upstream frequency band), it would be impossible to use current technologies that are built to detect a signal generated at the head end in the forward band.

In view of the fact that hybrid fiber-coaxial (HFC) cable distribution networks are evolving toward the high-split configuration, a new method for assessing leakage and measuring CLI, that can be operated in high frequencies, needs to be determined.

While the former methods were applicable in the 5-42 MHz frequency range, it may be tempting to consider that a leakage detected within this range has the same causes as a leakage in higher frequency ranges. We have found that this is not the case, as the leakage in the 5-42 MHz and leakage in the aeronautical frequencies are poorly correlated. It means that a fault that has a consequence in terms of leakage in the aeronautical frequency range may not be detected using tools and methodologies developed for the 5-42 MHz frequency range.

The aeronautical band is defined as the frequencies between 120-140 MHz. The high-split network therefore comprises electromagnetic signals with frequencies (5-200 MHz) encompassing the whole aeronautical band.

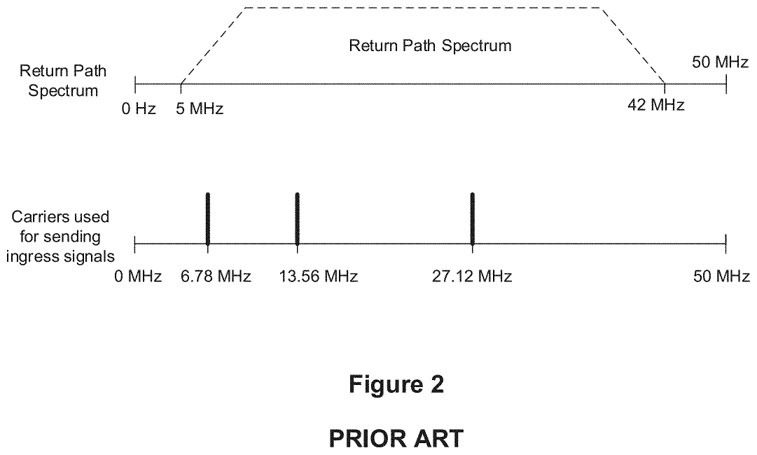

Formerly, leakage in the 5-42 MHz range were detected using transmitters and receivers using signals found in the 5-42 MHz range, as shown in FIG. 2. In view of the poor correlation studied by the inventor and mentioned above between leakage in the 5-42 MHz range and leakage in the 120-140 MHz, it appears that the leakage in the 120-140 MHz range (aeronautical band) should be detected by detecting leakage of electromagnetic signals with particular frequencies within the aeronautical band.

To continue using the current leakage detectors, the test signals would have to be generated by the cable modems of each of the clients. For an efficient detection, these signals should be generated continuously, which is not the case of the signals normally transmitted by the cable modems.

In any case, the leakage in the aeronautical band must be detected, and its intensity determined. The Cumulative Leakage Index (CLI), which denotes an estimate of the cumulative impacts of leakage on aeronautical spectrum users, must be determined based on the leakage measurements in the appropriate frequency range.

The method according to the invention comprises estimating the leakage in the aeronautical band (120-140 MHz) without having to measure the leakage itself. In other words, the location of a fault and the intensity of the leak in that frequency range are determined by avoiding introducing a signal at the headend and by further avoiding using a receiver in the environment to detect a leak and measure its intensity. These steps are not performed. Instead, the method according to the invention comprises estimating or assessing the severity of a leak in that band by measuring only the intensity of ingress from a fault. Since a leak acts like an antenna which emits electromagnetic signals, conversely, it can receive electromagnetic signals. The electromagnetic signals received by the fault acting as an antenna are then transmitted via the return channel back to the headend of the network, where they can be measured. It should be noted that, according to an embodiment, digital detection at the headend is possible using a remote PHY device (aka, a remote physical layer device). By applying a few extra steps, detailed below, an equivalency is determined between the measured ingress signal intensity and the egress (leak) intensity that would have been measured, should a receiver have been used instead by the worker in the field, thereby assessing the intensity of an egress leak from a fault (and also assessing CLI) by only measuring ingress signals instead, which we have determined to be equivalent, assuming that a correction is applied to the ingress measurements.

Using the principle of reciprocity of the antennas, it is indeed possible to measure the level of radiation by measuring the ingress level at the same frequency as the leak that would need to be detected. This approach (where the ingress is measured instead of the egress, not measured) has many advantages including that fact that it requires no test signal transmission by cable modems, detects actual and potential ingress points across the network, allows real-time detection in portable mode, and is compatible with former technologies such as the CPAT Flex® technology.

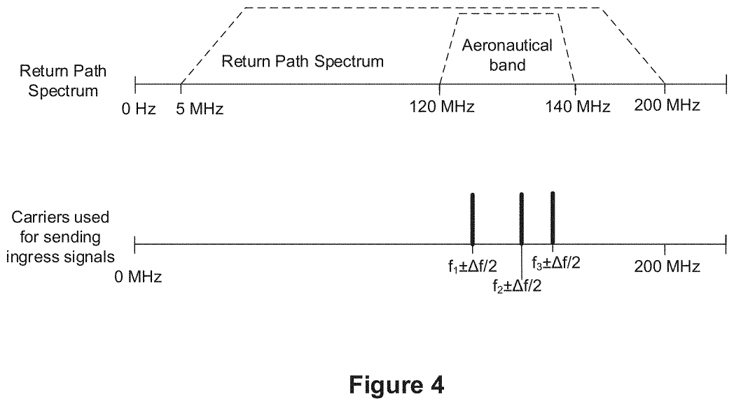

Currently, transmission from the field of frequencies in the aeronautical band (120-140 MHz) is not permitted in North America. The inventors contemplate that the legal framework should be updated to allow transmission in that range. More precisely, and referring to FIG. 4, the method should involve the transmission of only a few signal frequencies within the aeronautical band (120-140 MHz), and not a great plurality of frequencies across the whole range, as it would defeat the purpose of the minimization of environmental emissions of signals in the aeronautical band. Therefore, a few specific frequencies should be selected and allowed by the legal framework under which technicians would operate. These few specific signals would in fact have a central frequency (f₁, f₂, f₃, etc., to be selected within 120-140 MHz) and would have a frequency span about that central frequency of about 20-30 kHz (Δf). The few narrow bands (fₙ±Δf/2) chosen for leak detection would then be specifically legalized for the purpose of detecting network faults.

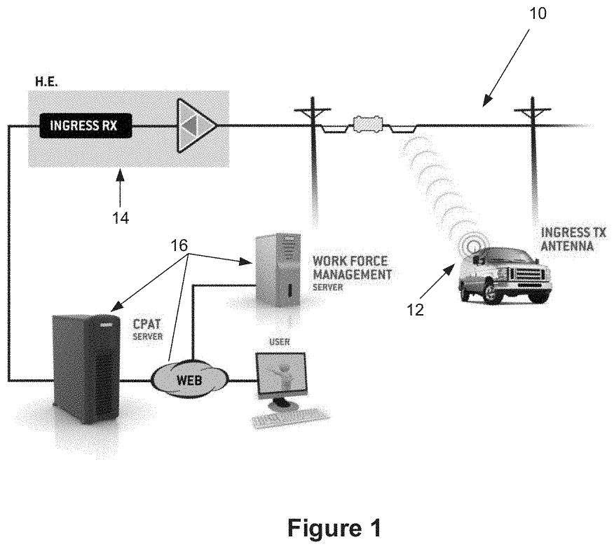

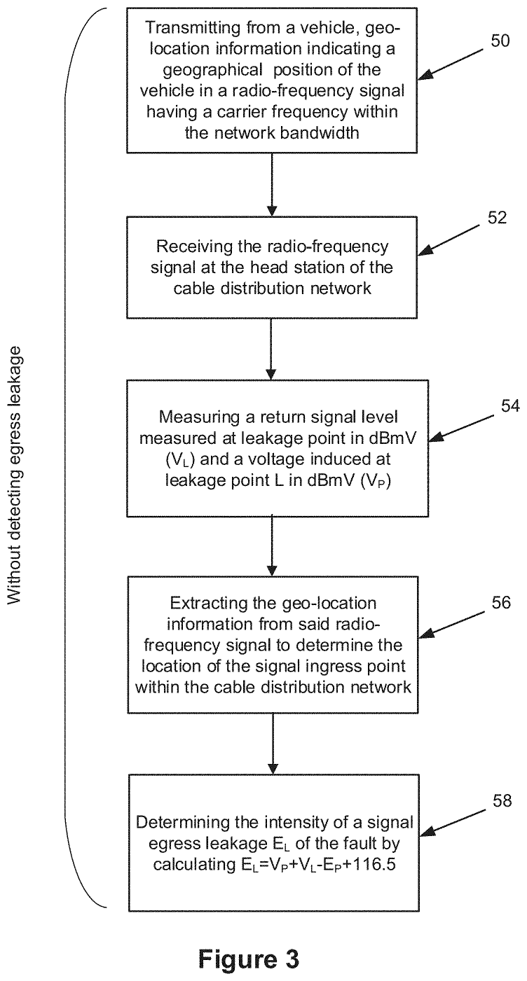

The present document describes a system and method for detecting and geo-locating signal egress (i.e., leakage) interferences in a cable distribution network, by measuring instead equivalent ingress interferences in a cable distribution network. The intermediate method for measuring ingress interferences in a cable distribution network is now described, in reference with FIGS. 1 and 3. The method for determining an equivalent leakage (egress) is then described further below, after having described the method for measuring ingress interferences.

The cable distribution network comprises a head station for transmitting content to subscribers at frequencies within a network bandwidth. The system comprises a vehicle mounted geo-locating device for generating geo-location data indicating the geographical position of a vehicle, and a vehicle mounted transmitter for transmitting a radio-frequency signal comprising said geo-location data using a carrier frequency within the network bandwidth as the vehicle travels within the geographical area of the network. If an ingress exists in the network, the ingress signal sent from onboard the vehicle would leak into the network and travel therein until it reaches a receiver installed at the head station of the cable distribution network. The receiver detects the radio-frequency signal and extracts therefrom the geo-location data indicating the position of the vehicle when the ingress signal was transmitted. In an embodiment, the receiver quantifies the relative level of the ingress source. A server is used to process the data extracted by the receiver to produces reports and maps reflecting ingress points in a geographical area.

In an embodiment, the system may further comprise a server implementing a web-based management application for processing the extracted geo-location information and identifying an ingress within the cable distribution network. The web-based management application may also be used to eliminate duplicates of the same ingress to avoid sending more than one repair team to the same ingress. In an embodiment the system generates an event map illustrating ingress/leak events within a geographical area.

In one aspect, the system for detecting signal ingress interferences is provided as a kit. The kit may comprise a vehicle mounted geo-locating device, e.g., a GPS, for identifying the location of the vehicle as the vehicle moves in the geographical area of the network, a wireless transmitter for transmitting the location of the vehicle as the vehicle is moving, an ingress detection receiver for detecting signals transmitted by the vehicle mounted transmitter which leaked into the cable distribution network through an ingress. The receiver may be installed at the head station of the cable distribution network, where cable signals are transmitted in the network. When the receiver detects a signal, it extracts the geo-location information transmitted in the signal for identifying the location of ingress.

In an embodiment, the kit may comprise a memory (CD, USB Key, or any other form of physical media) having recorded thereon computer readable instructions which, when executed by a processor, cause the processor to generate an event map illustrating ingress/leak events within a geographical area.

In a variation of this embodiment, the receiver groups recorded ingress points and transfers them through an internet access to a remote CPAT™ processing server. The processing server filters already known points and adds new ones in the database. The CPAT™ processing server produces reports and maps reflecting active content of the database.

The geo-locating device and the transmitter may be provided as separate components and may also be operatively combined with each other in a single unit.

Referring now to the drawings, FIG. 1 illustrates an example of an ingress locating system for detecting signal ingress interferences in accordance with an embodiment. In the embodiment shown in FIG. 1, the ingress locating system 10 includes a vehicle-based transmitter (ITX1) 12 (combined with a geo-locating device), a head-end located ingress detection receiver (IRX1) 14 and a server 16 implementing a web-based management application (CPAT™). The server may be in communication with a database or other servers and computers via a communication network such as the internet. The head-end ingress receiver 14 detects measures and localizes ingress events based on the ingress signals received at the receiver. The transmitter 12 transmits an over-the-air carrier containing the GPS coordinates of the vehicle position while the technician is driving out the plant during his daily work routine. In an embodiment, transmission of data (including the GPS coordinates) by the transmitter 12 lasts 6 ms to 8 ms. Transmission of data is repeated every 93 ms to 99 ms (96 ms±3 ms) in order to reduce repetitive collisions between transmission of multiples transmitters 12 in the same area. It is possible to accommodate a large number of vehicle mounted transmitters 12 provided in different vehicles. In an embodiment, the system may accommodate up to 500 transmitters 12 provided in different vehicles within the same cable plant. When the vehicle is driving in an ingress prone area, the transmitted signal enters the coaxial plant and travels up to the head-end location. Once identified, the signal is measured and decoded by the head-end ingress receiver 14. The information is then forwarded to the server 16.

In a non-limiting example of implementation, the user may select one or more carriers for sending the ingress test signals, where the carrier is centered at a frequency fₙ chosen between 120 and 140 MHz, the carrier spanning about the central frequency with a spread of about Δf where Δf is between 20-30 kHz, therefore having the carrier spanning from fₙ±10 kHz or ±15 kHz (i.e., Δf/2).

The power density of the transmitted signal should not exceed regulated limits for unintended emissions (especially in the context of the aeronautical band) and yet, it should be strong enough to be detected and decoded by the head-end ingress receiver 14. In an embodiment, the power density is adjustable. A preliminary evaluation of the operator's system upstream frequency allocation content may be performed to define upstream transmission frequency to avoid any interferences with operator services. Even if the transmitted level is very low, ingress test signals have to avoid the occupied upstream bands.

FIG. 2, representative of the prior art with respect to the goal of determining ingress as such, is a graphical illustration of possible carrier frequencies in the return spectrum for sending ingress signals. In the example of FIG. 2, the return path spectrum is between 5 and 42 MHZ, and the possible carrier frequencies include 6.78 MHz (with bandwidth extending between +/−15 KHZ), 13.56 MHZ (with bandwidth extending between +/−10 KHZ), and 27.12 MHZ (with bandwidth extending between +/−15 KHZ). As stated above, the user may select one or more of these carriers for sending the ingress test signals.

Keeping in mind that, according to the invention, the goal is determining egress (leakage) and not ingress, but the way to make this determination comprises the intermediate step of measuring ingress instead of egress, other frequencies can be chosen, as mentioned above, and as shown in FIG. 4.

FIG. 3 is a flowchart illustrating the steps of a method for determining equivalent egress leakage using detected signal ingress interferences, in accordance with an embodiment.

Step 50 includes transmitting from a vehicle, geo-location information indicating a geographical position of the vehicle in a radio-frequency signal having a carrier frequency within the aeronautical band, emitted at a transmitter power in a decibel scale, thereby defining E_{P}.

Step 52 includes receiving the radio-frequency signal at the head station of the cable distribution network.

Step 54 includes measuring a voltage variation with and without the radio-frequency signal received at the head station and converting into a decibel scale, thereby determining V_{diff}.

Step 56 includes extracting the geo-location information from said radio-frequency signal to estimate the location of the signal ingress within the cable distribution network which corresponds to location of the signal egress.

Step 58 includes determining the intensity of a signal egress leakage E_{L} of the fault by calculating E_{L}=E_{P}−V_{diff}. All the method is performed without actually detecting or measuring egress leakage, even though the ultimate goal is to estimate the egress leakage or other derivatives thereof (such as CLI). This formula will be shown below as being the equivalence relationship between ingress and egress for the same fault.

Objectives achieved by the system and method described herein include:
Ability to adapt to an upstream frequency plan used by broadband cable operator;
Non-interfering to any return services provided by broadband cable operator;
Robust digital modulation scheme to perform under severe noise conditions;
Using Available frequencies in the lower noisy part of the return band;
Ingress test signal frequencies, burst time and transmitted power compliant with FCC regulation;
Identify vehicle position within 6 feet radius from where ingress was detected;
Multiple and concurrent vehicle monitoring operation; and
Minimize equipment footprint and cost at the head-end.

The embodiments described herein can be implemented as a computer program product for use with a computer system. Such implementation may include a series of computer instructions fixed either on a tangible medium, such as a computer readable medium (e.g., a diskette, CD-ROM, ROM, or fixed disk) or transmittable to a computer system, via a modem or other interface device, such as a communications adapter connected to a network over a medium. The medium may be either a tangible medium (e.g., optical or electrical communications lines) or a medium implemented with wireless techniques (e.g., microwave, infrared or other transmission techniques). The series of computer instructions embodies all or part of the functionality previously described herein. Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies. It is expected that such a computer program product may be distributed as a removable medium with accompanying printed or electronic documentation (e.g., shrink wrapped software), preloaded with a computer system (e.g., on system ROM or fixed disk), or distributed from a server over the network (e.g., the Internet or World Wide Web). Of course, some embodiments of the invention may be implemented as a combination of both software (e.g., a computer program product) and hardware. Still other embodiments of the invention may be implemented as entirely hardware, or entirely software (e.g., a computer program product).

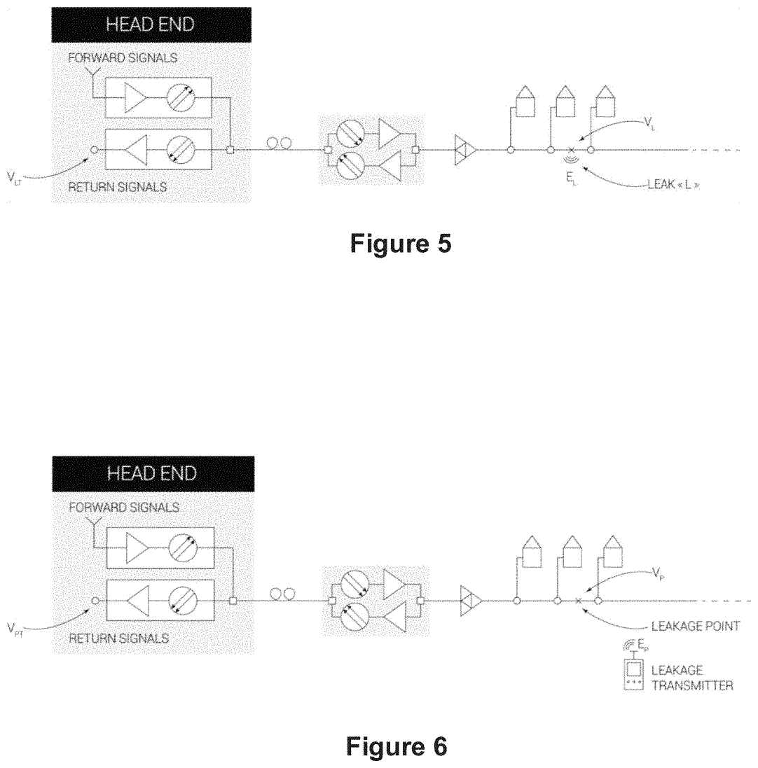

FIG. 5 is a schematic diagram which illustrates a high split network with a fault causing egress leakage, in accordance with an embodiment.

According to the antenna theory, one can easily demonstrate that the field intensity of the leak at 3 meters of the leakage point can be calculated as:

E_{L}=120+10 log(30)+G_{L}+V_{L}−78.8−20 log(d) [1]

where:
V_{L}: Return signal level measured at leakage point in (dBmV)
G_{L}: Leakage point relative gain in (dBᵢ)
E_{L}: Leak field intensity at 3 meters in (dBμV/m)
d: Measure distance (3 meters)

Assuming a distance d of 3 meters, then the equation [1] can be reduced to:

E_{L}=G_{L}+V_{L}+46.5 [2]

FIG. 6 is a schematic diagram which illustrates a high split network with a fault causing egress leakage, and being characterized by measuring ingress signals instead. The leakage transmitter is shown in FIG. 6, emitting radiation with a field E_{P}.

More specifically, according to the antenna theory, one can easily demonstrate that the induced voltage at the leakage point can be expressed as:

$${V}_{P} = {E}_{P} - 60 - 10 log ( \frac{{Z}_{0}}{{Z}_{r}} ) + {G}_{p} + 20 log ( λ ) - 10 log ( 4 π ) \qquad [ 3 ]$$

where
V_{P}: Voltage induced at leakage point L in (dBmV)
E_{P}: Field intensity radiated by leakage transmitter at 3 meters in dBμV/m
G_{P}: Leakage point relative gain in dBᵢ
   and
V_{LT}: Return signal level measured at the headend in (dBmV), not measured specifically according to the invention
V_{PT}: Voltage induced measured at the headend in (dBmV), not measured specifically according to the invention.

All values are expressed using dimensionless decibel scales.

Assuming a leak frequency of 120 MHz:
Z₀: Free space impedance (120π)
Zᵣ: Network impedance (75Ω)
λ=2.5 m

Then the equation [3] can be reduced to:

V_{P}=E_{P}+G_{P}−70 [4]

According to the theory of antenna reciprocity:

G_{L}=G_{P} [5]

Therefore:

V_{P}=E_{P}+G_{L}−70 [6]

Using equation [6], equation [2] then becomes:

E_{L}=V_{P}+V_{L}−E_{P}+116.5 [7]

That means that the equivalent leak intensity E_{L} is equal to the sum of the return signal level measured at leakage point in dBmV (V_{L}) and the voltage induced at leakage point L in (dBmV) (V_{P}), minus the transmitted test signal field intensity at 3 meters E_{P} (in dBμV/m), plus a definite constant.

The sum of V_{L}+V_{P} may actually be measured directly at the head-end, instead of measuring directly V_{L} and V_{P} at the leakage point. Therefore, a single measurement at the head-end replaces two measurements at the leakage point, which is very advantageous as a single measurement is required and it can be done at a single location (head-end) regardless of the location of the fault.

In other words, the sum V_{L}+V_{P} is measured at the head-end, and E_{P} is known (and constant) from the transmitter, therefore E_{L} can be found using Equation [7].

This is the relationship that makes the measured ingress interferences functionally equivalent to the egress leakage, such that the egress leakage can be determined by using ingress signals and by applying the relationship of Equation [7] to determine the leakage electromagnetic field based on the transmission power of the transmitter used in the field and the voltage difference measured at the headend. Assuming unity gain of the return network, the leak intensity level can be precisely estimated.

According to Equation [7], the leak intensity will be proportional to the sum of the return signal level and the test leakage signal level measured at the head end. The mobile transmitter has to be set up in order to transmit the test signal at a known field intensity E_{P} at 3 meters.

For example, the mobile transmitter has to be set up in order to transmit the test signal at a known field intensity E_{P} at 3 meters. The leak level will be calculated using the voltage different between the return signals and the test leakage signal at the head end (V_{diff}).

If E_{P}=54 dBμV/m at 3 meters, then the results, with different values for the measured V_{L}+V_{P}, are shown in Table 1 below, as calculated from Equation [7]. The values of E_{L} are shown both in decibels (result of the subtraction where all terms are in decibels) and also converted back to μV/m.

TABLE 1
Results of the leakage equivalence calculation

| V_{L} + V_{P}(dBmV) | E_{L}(dBμV/m) | E_{L}(μV/m) |
|---|---|---|
| 0 | 62.5 | 1334 |
| −5 | 57.5 | 750 |
| −10 | 52.5 | 422 |
| −15 | 47.5 | 237 |
| −20 | 42.5 | 133 |
| −25 | 37.5 | 75 |
| −30 | 32.5 | 42 |

While preferred embodiments have been described above and illustrated in the accompanying drawings, it will be evident to those skilled in the art that modifications may be made therein without departing from the scope of this disclosure. Such modifications are considered as possible variants comprised in the scope of the disclosure.

1. A method for locating and determining an intensity of a signal egress leakage of a fault, within a hybrid fiber-coaxial cable distribution network with an upstream frequency band encompassing an aeronautical band spanning over a range between 120 MHz and 140 MHz, the cable distribution network comprising a head station for transmitting content to subscribers at downstream frequencies within a network bandwidth, the method comprising:
transmitting from a vehicle, a radio-frequency signal having a carrier frequency within the aeronautical band, emitted at a transmitter power in a decibel scale, thereby defining E_{P};
receiving the radio-frequency signal at the head station of the cable distribution network,
measuring, at the head station, a sum (V_{P}+V_{L}) of a return signal level at leakage point (V_{L}) and a voltage induced at leakage point L (V_{P}) both converted into a decibel scale; and
determining the intensity of a signal egress leakage E_{L} of the fault by calculating E_{L}=V_{P}+V_{L}−E_{P}+116.5 in decibel scale.

2. A method for locating and determining an intensity of a signal egress leakage of a fault, without detecting or measuring the signal egress leakage, within a hybrid coaxial-fiber cable distribution network with an upstream frequency band encompassing an aeronautical band spanning over a range between 120 MHz and 140 MHz, the cable distribution network comprising a head station for transmitting content to subscribers at downstream frequencies within a network bandwidth, the method comprising:
transmitting from a vehicle, geo-location information indicating a geographical position of the vehicle in a radio signal having a carrier frequency within the aeronautical band, emitted at a transmitter power in a decibel scale E_{P};
receiving the radio signal at the head station of the cable distribution network,
measuring, at the head station, a sum (V_{L}+V_{P}) of a return signal level at leakage point in dBmV (V_{L}) and a voltage induced at leakage point L in dBmV (V_{P}) both converted into a decibel scale;
extracting geo-location information from said radio signal to determine the location of the signal ingress point within the cable distribution network; and
determining the intensity of a signal egress leakage E_{L} of the fault by calculating E_{L}=V_{P}+V_{L}−E_{P}+116.5 in decibel scale.
